(19) United States
(12) Patent Application Publication
(10) Pub. No.: US 2021/0359493 A1
(43) Pub. Date: Nov. 18, 2021

(54) OPTICAL SEMICONDUCTOR AMPLIFIER

(71) Applicant: TECHNISCHE UNIVERSITÄT BERLIN, Berlin (DE)

(72) Inventors: Ludwig GREIF, Berlin (DE); Andrei SCHLIWA, Storkow (DE)

(73) Assignee: TECHNISCHE UNIVERSITÄT BERLIN, Berlin (DE)

(21) Appl. No.: 17/286,813

(22) PCT Filed: Oct. 29, 2019
(86) PCT No.: PCT/EP2019/079530

§ 371 Date: Apr. 19, 2021

(30) Foreign Application Priority Data
Nov. 1, 2018 (EP) 18203957.8

(51) Int. Cl. H01S 5/34

(52) U.S. Cl. CPC H01S 5/3412

(57) ABSTRACT

The invention relates, inter alia, to an optical semiconductor amplifier (10), in which a plurality of quantum dots (QD) are arranged in at least one quantum dot layer (21-24) of a semiconductor element (11) of the semiconductor amplifier (10), wherein die semiconductor element (11) has a preferred direction (X) located in the quantum dot layer plane, and elongated quantum dots (QD) are present, each of which is longer in the said preferred direction (X) than in a transverse direction (Y) perpendicular thereto and is likewise located in the quantum dot layer plane. According to the invention, the beam amplification direction (SVR) of die semiconductor amplifier (10), which is defined by a fictitious connecting line (VL) between an input (A10) of the semiconductor amplifier (10) that serves for the irradiation of input radiation (Se), and an output (A10) of the semiconductor amplifier (10) that serves for outputting the amplified radiation (Sa), is arranged parallel, or at least approximately parallel, to the transverse direction (Y).

The invention relates to optical semiconductor amplifiers, to a method for producing optical semiconductor amplifiers, and to a method for operating an optical semiconductor amplifier.

The European patent EP 1 354 338 B1 discloses an optical semiconductor amplifier having the features as claimed in the preamble of patent claim 1, that is to say a semiconductor amplifier, wherein a multiplicity of quantum dots are arranged in a quantum dot layer of a semiconductor element of the semiconductor amplifier, wherein the semiconductor element has a preferred direction lying in the quantum dot layer plane, and elongated quantum dots are present, each of which is longer in said preferred direction than in a transverse direction perpendicular thereto and likewise lying in the quantum dot layer plane.

The invention is based on the object of specifying a semiconductor amplifier having a particularly high gain.

This object is achieved according to the invention by means of an optical semiconductor amplifier having the features as claimed in patent claim 1. Advantageous configurations of the semiconductor amplifier according to the invention are specified in dependent claims.

Accordingly, the invention provides for the beam amplification direction of the semiconductor amplifier, which is defined by a fictitious connecting line between an input of the semiconductor amplifier, said input serving for radiating in input radiation, and an output of the semiconductor amplifier, said output serving for outputting the amplified radiation, to be arranged parallel or at least approximately parallel to the transverse direction.

A major advantage of the semiconductor amplifier according to the invention consists in the high gain thereof, which is based on the orientation of the elongated quantum dots provided according to the invention.

It is considered to be advantageous if for more than 50% of the elongated quantum dots the length in the preferred direction is at least 1.5 times, preferably between 1.8 times and 2.4 times, the length of the quantum dots in the transverse direction.

Preferably, at least two quantum dot layers which are parallel to one another and each have a multiplicity of elongated quantum dots are present.

The quantum dots preferably lie one above another in alignment. The quantum dots respectively lying one above another preferably form elongated quantum dot columns.

The quantum dots in the elongated quantum dot columns are preferably quantum mechanically coupled.

One preferred configuration provides for the quantum dots lying one above another to touch one another.

Alternatively, the quantum dots lying one above another can also be separated from one another by one or more separating layers; the separating layers are preferably thin enough that the quantum mechanical coupling of the quantum dots is maintained.

The ratio between the height of the quantum dot columns and the length of the column base area in the preferred direction is preferably in each case 1 or is preferably at least in a range of between 0.9 and 1.1.

The longitudinal direction of the quantum dot columns preferably extends in the [001] crystal direction.

The preferred direction mentioned is preferably the [110] crystal direction.

The transverse direction mentioned is preferably the crystal direction.

In one preferred embodiment variant, it is provided that in each of the quantum dot layers in each case at least 50% of the quantum dots have a length in the preferred direction which is at least 1.5 times the length of the elongated quantum dots in the transverse direction.

The beam amplification direction preferably lies in the quantum dot layer or the quantum dot layers or at least approximately in or parallel to the quantum dot layer or quantum dot layers.

The shift angle between the beam amplification direction and the transverse direction and the shift angle between the beam amplification direction and the quantum dot layer are preferably in each case less than 1°.

The length of the quantum dots as viewed in the preferred direction is preferably less than 40 nm and/or less than the de Broglie wavelength of the electrons in the quantum dot material. Consequently, the quantum dots are preferably not quantum wires.

The invention furthermore relates to a method for producing an optical semiconductor amplifier, in particular for producing an optical semiconductor amplifier such as has been described above or is defined in the patent claims, wherein in the method a multiplicity of quantum dots are produced by virtue of the fact that quantum dot material is applied on a layer of the semiconductor element and a beam amplification direction of the semiconductor amplifier is defined by a fictitious connecting line between an input of the semiconductor amplifier, said input serving for radiating in input radiation, and an output of the semiconductor amplifier, said output serving for outputting the amplified radiation.

With regard to such a method, the invention provides for the plurality of quantum dots to be produced as elongated quantum dots which are longer in a preferred direction of the semiconductor element, said preferred direction lying in the quantum dot layer plane, than in a transverse direction perpendicular thereto and likewise lying in the quantum dot layer plane, and the beam amplification direction to be arranged parallel or at least approximately parallel to said transverse direction.

With regard to the advantages of the method according to the invention, reference should be made to the above explanations in association with the semiconductor amplifier according to the invention.

It is advantageous if for more than 50% of the quantum dots the length in the preferred direction of the semiconductor element is produced such that it is at least 1.5 times greater than in the transverse direction.

In one embodiment variant considered to be particularly advantageous, it is provided that quantum dot material for forming the quantum dots is grown indirectly or directly onto a (001) substrate and the [001] crystal direction is selected as growth direction when applying the quantum dot material, the preferred direction of the semiconductor element is the [110] crystal direction, and the transverse direction is the [110] crystal direction.

Preferably, a quantum dot column layer having at least two quantum dot layers which are parallel to one another and each have a multiplicity of elongated quantum dots is produced. The quantum dots are preferably grown one above another in alignment, and the quantum dots respectively lying one above another preferably form elongated quantum dot columns along the preferred direction.

The quantum dots in the elongated quantum dot columns are preferably produced with no distance with respect to one another or with only a small distance with respect to one another. In the case of a distance between quantum dots lying one directly above another, the distance is preferably chosen to be so small that the quantum dots are quantum mechanically coupled.

One particularly preferred variant provides for the quantum dots in the elongated quantum dot columns to be grown one directly on top of another, such that they touch one another. Alternatively, separating layers can also be provided; however, they are preferably in each case all or jointly thin enough that a quantum mechanical coupling of the quantum dots is attained or maintained.

The ratio between the height of the quantum dot columns and the length of the column base area in the transverse direction is preferably set to a value of 1 or at least to a value in the range of between 0.9 and 1.1.

The longitudinal direction of the quantum dot columns preferably extends in the [001] crystal direction.

The quantum dots are preferably grown.

The growth temperature during the growth of the quantum dots is preferably set to be greater than 500° C.

The growth rate during the growth of the quantum dots is preferably set to be greater than 0.2 μm/h.

Moreover, it is advantageous if a barrier layer of at least 10 nm is produced in order to direct the operating or injection current in a targeted manner into the region of the quantum dot columns and to obtain a particularly high current density there.

As elongated quantum dots, preferably self-assembled InAs quantum dots are grown by metal organic vapor phase epitaxy or molecular beam epitaxy.

The quantum dots, as viewed in the preferred direction, are preferably produced such that they are shorter than 40 nm and/or shorter than the de Broglie wavelength of the electrons in the quantum dot material.

It is advantageous if at least two, in particular between 5 and 10, quantum dot layers which are parallel to one another and each have a multiplicity of quantum dots are produced, wherein in each of the quantum dot layers in each case at least 50% of the elongated quantum dots have a length in the preferred direction which is at least 1.5 times the length of the quantum dots in the transverse direction.

The beam amplification direction preferably lies in the quantum dot layer or in the quantum dot layers or at least approximately in or parallel to the quantum dot layer or the quantum dot layers.

The shift angle between the beam amplification direction and the transverse direction and the shift angle between the beam amplification direction and the quantum dot layer are preferably set in each case to be less than 1°.

The invention furthermore relates to a method for operating an optical semiconductor amplifier, in particular an optical semiconductor amplifier such as has been described above or is defined in the patent claims. The invention provides for optical radiation to be radiated in at the input of the semiconductor amplifier along a direction with a shift angle of less than 30° relative to the transverse direction of the elongated quantum dots, and the amplified radiation to be coupled out of the semiconductor amplifier along this beam direction at the output of said semiconductor amplifier.

With regard to the advantages of the last-mentioned method, reference should be made to the above explanations in association with the semiconductor amplifier according to the invention.

The invention is explained in greater detail below on the basis of exemplary embodiments; in the figures by way of example

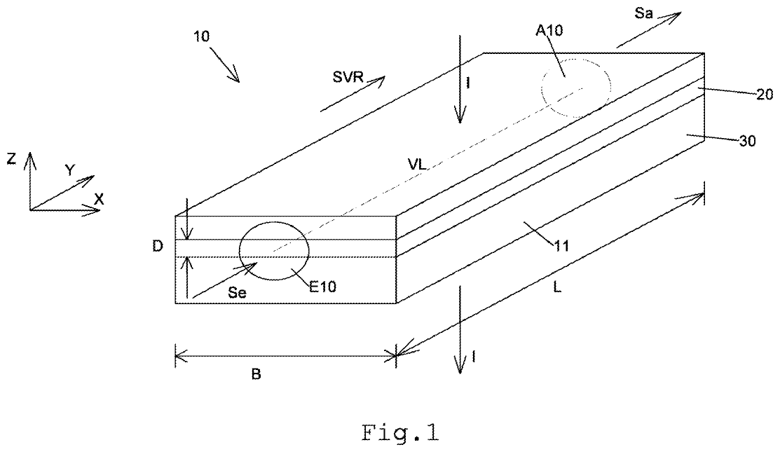

FIG. 1 shows an exemplary embodiment of an optical semiconductor amplifier according to the invention in a three-dimensional view obliquely from the side,

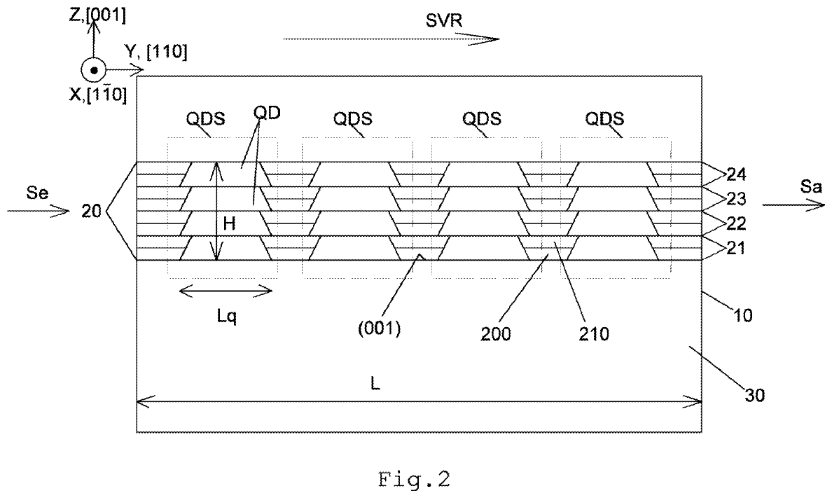

FIG. 2 shows a longitudinal section through the semiconductor amplifier in accordance with FIG. 1 for illustrating by way of example quantum dot columns in a quantum dot column layer of the semiconductor amplifier in accordance with FIG. 1,

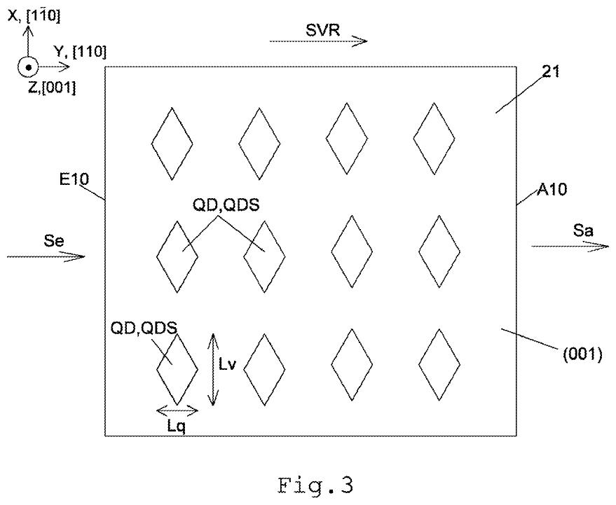

FIG. 3 shows a plan view of a quantum dot layer of the quantum dot column layer in the semiconductor amplifier in accordance with FIG. 1,

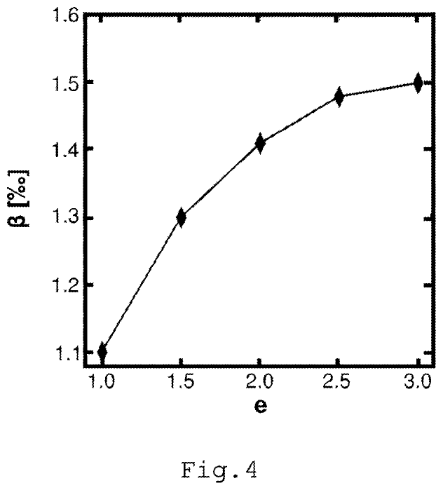

FIG. 4 shows the β-factor as a function of the elongation e,

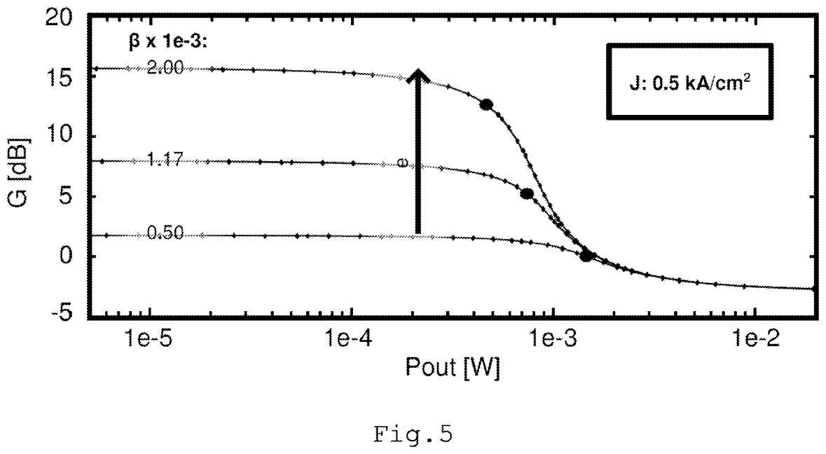

FIG. 5 shows the gain G as a function of the optical output power Pout for an injection current with a current density of J=0.5 kA/cm² and various β-factors,

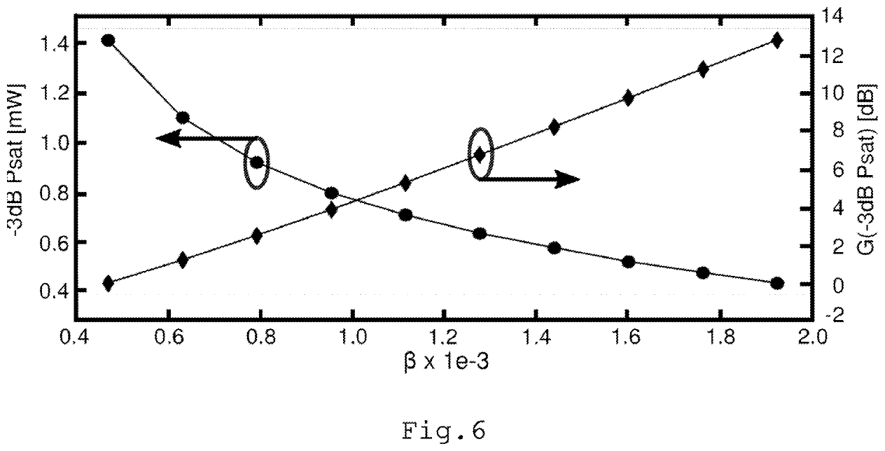

FIG. 6 shows the 3 dB saturation power −3 db Psat and the 3 dB saturation gain G(−3 dB Psat) as a function of the β-factor,

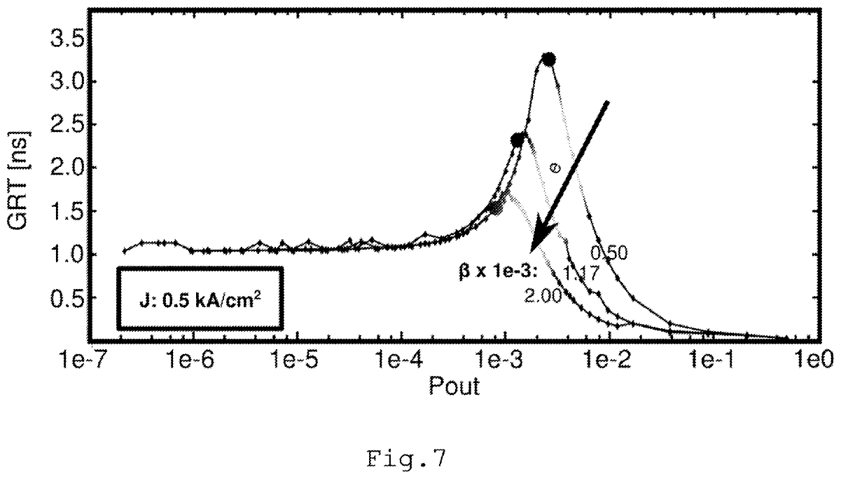

FIG. 7 shows the gain recovery time GRT versus the optical output power Pout depending on the elongation e for an injection current with a current density of J=0.5 kA/cm², and

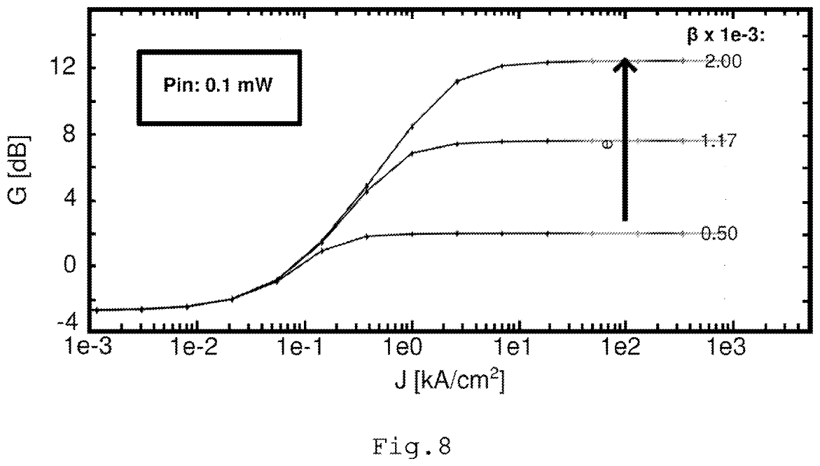

FIG. 8 shows the gain G as a function of the injection current density J for an optical input power of 0.1 mW and various β-factors.

In the figures, the same reference signs are always used for identical or comparable components, for the sake of clarity.

FIG. 1 shows in a three-dimensional view obliquely from the side an exemplary embodiment of a quantum-dot-based optical semiconductor amplifier (also referred hereinafter for short as QD-SOA) 10 having an optical input E10 for radiating in optical input radiation Se. An optical output A10 of the semiconductor amplifier 10 is situated in alignment with the input E10 along a beam amplification direction SVR, at which optical output amplified optical radiation Sa is output on the output side. The fictitious connecting line between the input E10 and the output A10 is identified by the reference sign VL in FIG. 1.

For the purpose of optically amplifying the input radiation Se, the optical semiconductor amplifier 10 comprises a semiconductor element 11 having a quantum dot column layer 20, which bears or is grown indirectly or directly, as shown by way of example in FIG. 1, on a substrate 30 of the semiconductor element 11.

The optical semiconductor amplifier 10 in accordance with FIG. 1 is preferably operated as follows:

An electric field is applied externally in order to bring about an electric current I through the quantum dot column layer 20. The current I flows perpendicularly to the layer plane of the quantum dot column layer 20 and supplies the quantum dots situated in the quantum dot column layer 20 with energy for amplifying the input radiation Se. The optical input radiation Se is radiated in parallel or at least approximately parallel to the fictitious connecting line L between the input E10 and the output A10 of the semiconductor amplifier or parallel to the beam amplification direction SVR.

FIG. 2 shows a longitudinal section through the optical semiconductor amplifier 10 in more specific detail. The substrate 30 and the quantum dot column layer 20 situated thereon are evident. The quantum dot column layer 20 comprises a multiplicity of quantum dot layers, four of which are illustrated by way of example and identified by the reference signs 21, 22, 23 and 24 in FIG. 2.

Each of the quantum dot layers 21, 22, 23 and 24 has in each case a multiplicity of quantum dots QD, which quantum dots or the base areas of which quantum dots along a preferred direction identified by the reference sign X in FIGS. 1 and 2 are longer than in the transverse direction Y perpendicular thereto and likewise lying in the plane of the quantum dot layers 21 to 24 or the plane of the quantum dot column layer 20 and corresponding to the beam amplification direction SVR in accordance with FIG. 1.

The quantum dots QD in the quantum dot layers 21 to 24 are arranged one above another in alignment, thus forming quantum dot columns QDS having in each case quantum dots QD lying one above another.

In the exemplary embodiment in accordance with FIG. 2, the quantum dots QD of each quantum dot column QDS lie one directly above or on top of another and are not separated from one another by any intermediate layer. By virtue of the quantum dots QD of the quantum dot columns QDS lying one directly on top of another, this results in a quantum mechanical coupling of the quantum dots within the respective quantum dot column QDS.

Alternatively, the quantum dot layers 21 to 24 can also have further layers resulting in a spatial separation of the quantum dots QD from one another in the respective quantum dot column QDS; in the case of such an embodiment, however, it is advantageous if the separating layers between the quantum dots QD lying one directly above another are in each case thin enough to maintain the quantum mechanical coupling of the quantum dots QD in each of the quantum dot columns QDS, as is the case for quantum dots QD lying one directly on top of another.

Each of the quantum dot layers 21 to 24 preferably comprises in each case a lower wetting layer 200, these being grown with the quantum dots, and a barrier layer 210 situated thereon.

The material of the lower wetting layers 200 and the quantum dot material of the quantum dots QD situated thereon are preferably identical in each case, as shown in FIG. 2, such that in the region of the quantum dots QD the layer portion of the wetting layer 200 respectively situated there itself forms the lower part of the respective quantum dot QD.

The material of the barrier layers 210 preferably has a larger band gap than the quantum dot material, thus resulting in a vertical current I (cf. FIG. 1) through the quantum dot column layer 20 exclusively or at least predominantly only in the region of the quantum dots QD or quantum dot columns QDS.

The height of the quantum dot columns QDS or the layer thickness of the quantum dot column layer 20 is identified by the reference sign H in FIG. 2. The length of the individual quantum dots QD in the preferred direction X is identified by the reference sign Lv. The ratio between the height H of the quantum dot columns QDS and the length Lv of the quantum dots QD in the preferred direction X is preferably in a range of between 0.9 and 1.1. Particularly preferably, the ratio is 1 or at least approximately 1.

The elongation of the quantum dots QD, which will be discussed in even more specific detail further below in association with FIGS. 4 to 8, is defined as follows for the illustration in FIG. 4:

e=Lv/Lq

wherein e denotes the elongation. The lengths Lv and Lq respectively refer to the lower base area of the quantum dots QD which itself forms the underside of the respective quantum dot layer 21 to 24 or faces the latter if it does not itself form the latter, but rather is separated from the latter by an additional separating layer.

It is considered to be particularly advantageous if the crystal plane of the substrate 30 on which the quantum dot column layer 20 is situated is a (001) crystal plane. Moreover, it is advantageous if the abovementioned preferred direction X along which the quantum dots QD are elongated is formed by the [110] crystal direction of the substrate 30 or of the layer material of the quantum dot column layer 20 situated thereon and the transverse direction Y is a [110] crystal direction.

The substrate 30 is preferably a GaAs substrate. The quantum dot material is preferably InAs or InₓGA₍ₓ₋₁₎As material.

FIG. 3 shows the quantum dot layer 21 of the quantum dot column layer 20 of the semiconductor amplifier 10 in accordance with FIGS. 1 and 2 in a plan view. The quantum dots QD of the quantum dot layer 21 can be discerned. It is evident that the quantum dots QD are longer along the preferred direction X (here the [110] crystal direction) than in the transverse direction Y (here the [110] crystal direction). The ratio between the length Lv along the preferred direction X and the length Lq along the transverse direction Y is preferably 1.5 or more, particularly preferably between 1.8 and 2.4.

As a result of the orientation—shown in FIG. 3—of the elongated quantum dots QD relative to the beam amplification direction SVR or to the fictitious line VL between the input E10 and the output A10 of the optical amplifier 10, what happens is that the optical radiation Se, upon passing through the optical semiconductor amplifier 10, passes through the quantum dots QD in each case along the transverse direction Y, whereby relevant advantages can be obtained, which will be explained in greater detail by way of example hereinafter.

As a result of the great elongation in the exemplary embodiment in accordance with FIGS. 1 to 3, the probability of photons being emitted perpendicularly to the elongated axis X rises significantly. Since this likewise applies to the probability of stimulated emission, the gain of the entire semiconductor amplifier 10 can be increased as a result.

Specifically, the elongation of the quantum dots results in structural symmetry breaking in the (001) plane. As a consequence, real and imaginary parts of the complex transition dipole moment p are oriented increasingly parallel at the elongated axis X. The probability of a transition of the excited electron to the ground state as a result of spontaneous emissions B21, according to Fermi's golden rule, is proportional to the orientation of the photon polarization and the transition dipole moment:

B21∝(εμ)²

Thus, depending on the manifestation of the elongation, preference is given to electronic transitions with participation of photons with a polarization along the preferred direction X or different polarizations are almost completely suppressed. Since the direction of propagation of photons is perpendicular to their polarization, a preference for the polarization along the elongated axis, that is to say the preferred direction X, results in a preferred propagation in the plane perpendicular thereto. Since it holds true, moreover, that the probability of stimulated emission A21 is proportional to B21, this also entails the increase in the probability of stimulated emission with a corresponding direction of propagation.

Theoretical Background and Modeling

The inventors simulated the electronic and optical properties of stacked InAs quantum dots in GaAs with the aid of an 8-band kp model taking account of the influence of crystal distortion and the first and second order piezoelectric fields resulting therefrom. The electronic properties were taken as a basis for calculating the emission characteristic of spontaneous emission for the stacked quantum dots. This means that on the basis of the concrete geometric structure of the stacked quantum dots, the rate of spontaneously emitted photons was determined depending on an individual solid angle element. In this case, the total solid angle was resolved by 10 000 equidistantly distributed interpolation points. By means of geometric considerations, depending on a set of component dimensions of an exemplary component, it was then possible to determine the proportion β of the photons which propagates within the active zone of the amplifier and can leave the component. This proportion was included in an extended Ben-Ezra rate equation model for QD-SOAs (quantum dot semiconductor amplifiers), in which the β-dependent rate of stimulated emissions was incorporated. With the aid of a fourth order Runge-Kutta method, the rate equation model was used to simulate a pump-probe experiment for a multiplicity of different signal powers and the β-values determined previously. From the data it was possible to determine the following values as a function of β, the signal output powers and the injection current density J:
the gain G,
the 3 dB saturation power −3 dB Psat
the 3 dB saturation gain G(−3 dB Psat) (canonical index for the upper limit of signal power amplified without errors) and
the gain recovery time GRT.

In this case, the simulation was carried out specifically for a quantum dot semiconductor optical amplifier (QD-SOA) with the following exemplary component specifications:
quantum dot planes (number of quantum dot layers within a quantum dot column layer 20 in accordance with FIGS. 1 to 3): 7
length L of the active zone: along the beam amplification direction SVR or the transverse direction Y: 2 mm
height H of the active zone or layer thickness of the quantum dot column layer 20: 0.2 μm
width B of the active zone or the quantum dot column layer in the preferred direction X: 10 μm
quantum dot density 5*10¹⁰ cm⁻²
injection current density J: 1*10⁻³ kA/cm² to 1*10³ kA/cm²
input signal power Pin: 1*10⁻⁷ W to 1 W

Without restricting the generality, the influence of elongation in the case of perpendicular orientation of the optical and elongated axis X for an InGaAs quantum dot semiconductor optical amplifier, also called InGaAs-QD-SOA hereinafter, is presented by way of example below. For the calculation of the β-coefficients, which proceeds independently of the QD-SOA simulation, a series of five stacked InAs/GaAs quantum dots or quantum dot columns having an elongation e of between 1 and 3 (see FIG. 4) was calculated. The number of stacked quantum dots is not varied here since as a rule it is fixed by the intention of polarization independence in the gain properties. The reduction to four quantum dots undertaken here by way of example is due to the significantly reduced computation time and the fact that extensive calculations performed in the context of research work in the inventors' working group suggest that the number of stacked quantum dots does not have a significant influence on the optical properties in the (001) plane.

The results in FIG. 4 show that the rate of stimulated emissions and hence likewise of the β-factor can rise by almost 36% in the context of the elongations considered. It was ascertained that in the case of an orthogonally oriented optical and elongated axis X, a larger elongation also entails a higher β-factor. If the same variation range of the β-factor is used for the simulation of the abovementioned characteristic variables of the QD-SOA with the aid of the Ben-Ezra rate equation model, this yields a number of significant improvements, four of which are described in more specific detail below:

1. Improved Gain for all Powers

If the gain G is represented as a function of the optical output power Pout (see FIG. 5) or versus the current density J (see FIG. 8), then the increased gain values for higher β-factors is immediately evident. What is furthermore found is a plateau (linear amplifier range) for low powers, which is typical of all amplifiers, followed by a great decrease in gain (nonlinear amplifier range). In order to delimit the linear amplifier range suitable for operation from the nonlinear amplifier range, it is possible to define the 3 dB saturation output power −3 dB Psat, at which the gain G was reduced by 3 dB relative to its maximum value.

2. Significantly Increased Saturation Gain

If the associated 3 dB saturation gain G (−3 db Psat) (see FIG. 6) is represented as a function of the β-factor, the potential of the invention is revealed. As a result of an increase in the β-factor owing to the use of greatly elongated quantum dots from 1.1‰ to 1.5‰, the saturation gain for the simulated QD-SOA can rise from 4.8 dB to 8.5 dB. The logarithmic nature of the dB scale should be taken into consideration here. The increases by 3.7 dB corresponds to a percentage increase in the ratio of the output powers by 134%.

3. Reduced Gain Recovery Time in the Upper Operating Range

As already mentioned, besides the gain, the gain recovery time GRT is an elementary characteristic variable for amplifiers of all types. It describes how rapidly the system is ready for renewed amplification after having amplified a pulse and thus describes the limit of the maximum signal frequency. On account of the short gain recovery times of less than 1 ns, the field of radio-frequency signal amplification represents the actual strength of QD-SOAs. If the influence of the β-factor on the gain recovery time is considered (see FIG. 7), it becomes clear that no change can be discerned for the overwhelming majority of the operating range, that is to say Pout<saturation output power. If the output power approaches the saturation output power, it can even be discerned that a further reduction of the gain recovery time is possible with the aid of the elongation e.

In conclusion, it can be stated that QD-SOAs of the type described by way of example above are convincing owing to their unique radio-frequency properties. The saturation gain can be almost doubled by an elongation e of 3.0. In this case, the radio-frequency properties are not influenced by the elongation, depending on signal power, or can be improved even further.

Although the invention has been more specifically illustrated and described in detail by means of preferred exemplary embodiments, nevertheless the invention is not restricted by the examples disclosed and other variations can be derived therefrom by the person skilled in the art, without departing from the scope of protection of the invention.

### LIST OF REFERENCE SIGNS

10 Semiconductor amplifier
11 Semiconductor element
20 Quantum dot column layer
21 Quantum dot layer
22 Quantum dot layer
23 Quantum dot layer
24 Quantum dot layer
30 Substrate
200 Wetting layer
210 Barrier layer
A10 Output
E10 Input
e Elongation
G Gain
GRT Gain recovery time
H Height
I Current
J Current density
L Length
Lq Length
Lv Length
Pase Power
Pout Optical output power
Psig Output power
QD Quantum dot
QDS Quantum dot column
Sa Radiation
Se Input radiation
SVR Beam amplification direction
VL Fictitious connecting line
X Preferred direction
Y Transverse direction

1. An optical semiconductor amplifier (10), wherein a multiplicity of quantum dots (QD) are arranged in at least one quantum dot layer (21-24) of a semiconductor element (11) of the semiconductor amplifier (10), wherein the semiconductor element (11) has a preferred direction (X) lying in the quantum dot layer plane, and elongated quantum dots (QD) are present, each of which is longer in said preferred direction (X) than in a transverse direction (Y) perpendicular thereto and likewise lying in the quantum dot layer plane,
characterized in that
the beam amplification direction (SVR) of the semiconductor amplifier (10), which is defined by a fictitious connecting line (VL) between an input (A10) of the semiconductor amplifier (10), said input serving for radiating in input radiation (Se), and an output (A10) of the semiconductor amplifier (10), said output serving for outputting the amplified radiation (Sa), is arranged parallel or at least approximately parallel to the transverse direction (Y).

2. The semiconductor amplifier (10) as claimed in claim 1,
characterized in that
for more than 50% of the elongated quantum dots (QD) the length (Lv) in the preferred direction (X) is at least 1.5 times the length (Lq) of the quantum dots (QD) in the transverse direction (Y).

3. The semiconductor amplifier (10) as claimed in claim 1,
characterized in that
for more than 50% of the elongated quantum dots (QD) the length (Lv) in the preferred direction (X) is between 1.8 times and 2.4 times the length (Lq) of the quantum dots (QD) in the transverse direction (Y).

4. The semiconductor amplifier (10) as claimed in claim 1,
characterized in that
at least two quantum dot layers (21-24) which are parallel to one another and each have a multiplicity of elongated quantum dots (QD) are present,
the quantum dots (QD) lie one above another in alignment, and
the quantum dots (QD) respectively lying one above another form elongated quantum dot columns (QDS).

5. The semiconductor amplifier (10) as claimed in claim 4,
characterized in that
the quantum dots (QD) in the elongated quantum dot columns (QDS) are quantum mechanically coupled.

6. The semiconductor amplifier (10) as claimed in claim 5,
characterized in that
in each of the quantum dot layers (21-24) in each case at least 50% of the quantum dots (QD) have a length (Lv) in the preferred direction (X) which is at least 1.5 times the length (Lq) of the elongated quantum dots (QD) in the transverse direction (Y).

7. The semiconductor amplifier (10) as claimed in claim 4,
characterized in that
the ratio between the height (H) of the quantum dot columns (QDS) and the length (Lv) of the column base area in the preferred direction (X) is in each case 1 or is at least in a range of between 0.9 and 1.1.

8. The semiconductor amplifier (10) as claimed in claim 1,
characterized in that
the longitudinal direction of the quantum dot columns (QDS) extends in the [001] direction.

9. The semiconductor amplifier (10) as claimed in claim 1,
characterized in that
the preferred direction (X) is the [11̅0] crystal direction of the quantum dot layer or quantum dot layers, and
the transverse direction (Y) is the [110] crystal direction of the quantum dot layer or quantum dot layers.

10. A method for producing an optical semiconductor amplifier (10), in particular for producing an optical semiconductor amplifier (10) as claimed in any of the preceding claims, wherein in the method a multiplicity of quantum dots (QD) are produced by virtue of the fact that quantum dot material is applied on a layer of the semiconductor element (11) and a beam amplification direction (SVR) of the semiconductor amplifier (10) is defined by a fictitious connecting line (VL) between an input (A10) of the semiconductor amplifier (10), said input serving for radiating in input radiation (Se), and an output (A10) of the semiconductor amplifier (10), said output serving for outputting the amplified radiation (Sa),
characterized in that
the plurality of quantum dots (QD) are produced as elongated quantum dots (QD) which are longer in a preferred direction (X) of the semiconductor element (11), said preferred direction lying in the quantum dot layer plane, than in a transverse direction (Y) perpendicular thereto and likewise lying in the quantum dot layer plane, and
the beam amplification direction (SVR) is arranged parallel or at least approximately parallel to said transverse direction (Y).

11. The method as claimed in claim 10,
characterized in that
quantum dot material for forming the quantum dots (QD) is grown indirectly or directly onto a (001) substrate (30) and the [001] crystal direction is selected as growth direction when applying the quantum dot material,
the preferred direction (X) of the semiconductor element (11) is the [11̅0] crystal direction, and
the transverse direction (Y) is the [110] crystal direction.

12. The method as claimed in claim 10,
characterized in that
a quantum dot column layer (20) having at least two quantum dot layers (21-24) which are parallel to one another and each have a multiplicity of elongated quantum dots (QD) is produced, and
the quantum dots (QD) are grown one above another in alignment, and the quantum dots (QD) respectively lying one above another form elongated quantum dot columns (QDS) along the preferred direction (X).

13. The method as claimed in claim 12,
characterized in that
the quantum dots (QD) in the elongated quantum dot columns (QDS) are produced with no distance or at most with such a small distance with respect to one another that quantum dots (QD) lying one above another are quantum mechanically coupled.

14. The method as claimed in claim 13,
characterized in that
the quantum dots (QD) in the elongated quantum dot columns (QDS) are grown one directly on top of another, such that they touch one another.

15. The method as claimed in claim 10,
characterized in that
the ratio between the height (H) of the quantum dot columns (QDS) and the length (Lv) of the column base area in the preferred direction (X) is set to a value of 1 or at least to a value in the range of between 0.9 and 1.1.

16. (canceled)

17. A method for operating an optical semiconductor amplifier (10), wherein a multiplicity of quantum dots (QD) are arranged in at least one quantum dot layer (21-24) of a semiconductor element (11) of the semiconductor amplifier (10), wherein the semiconductor element (11) has a preferred direction (X) lying in the quantum dot layer plane, and elongated quantum dots (QD) are present, each of which is longer in said preferred direction (X) than in a transverse direction (Y) perpendicular thereto and likewise lying in the quantum dot layer plane,
characterized in that
the beam amplification direction (SVR) of the semiconductor amplifier (10), which is defined by a fictitious connecting line (VL) between an input (A10) of the semiconductor amplifier (10), said input serving for radiating in input radiation (Se), and an output (A10) of the semiconductor amplifier (10), said output serving for outputting the amplified radiation (Sa), is arranged parallel or at least approximately parallel to the transverse direction (Y), and
optical radiation (Sa) is radiated in at the input (A10) of the semiconductor amplifier (10) along a direction with a shift angle of less than 30° relative to the transverse direction of the elongated quantum dots, and the amplified radiation (Sa) is coupled out of the semiconductor amplifier (10) along this beam direction at the output (A10) of said semiconductor amplifier (10).

18. The method as claimed in claim 17,
characterized in that
the optical radiation (Sa) is radiated in at the input (A10) of the semiconductor amplifier (10) parallel to the transverse direction of the elongated quantum dots, and the amplified radiation (Sa) is coupled out of the semiconductor amplifier (10) along this beam direction at the output (A10) of said semiconductor amplifier (10).

19. An optical semiconductor amplifier (10), wherein a multiplicity of quantum dots (QD) are arranged in at least one quantum dot layer (21-24) of a semiconductor element (11) of the semiconductor amplifier (10), wherein the semiconductor element (11) has a preferred direction (X) lying in the quantum dot layer plane, and elongated quantum dots (QD) are present, each of which is longer in said preferred direction (X) than in a transverse direction (Y) perpendicular thereto and likewise lying in the quantum dot layer plane,
characterized in that
the semiconductor amplifier (10) has an input (E10) for radiating in input radiation (Se) and an output (A10) for outputting the amplified radiation (Sa),
a fictitious connecting line (VL) between the input (E10) and the output (A10) defines the beam amplification direction (SVR) of the semiconductor amplifier (10), and
the fictitious connecting line (VL) between the input (E10) and the output (A10) is arranged parallel or at least approximately parallel to the transverse direction (Y).
